(19) United States
(12) Patent Application Publication
(10) Pub. No.: US 2026/0371634 A1
(43) Pub. Date: Nov. 19, 2026

(54) SEMICONDUCTOR STRUCTURE INCLUDING HIGH THERMAL CONDUCTIVITY MATERIAL AND METHOD OF FORMING THE SAME

(71) Applicant: Taiwan Semiconductor Manufacturing Company, Ltd., Hsinchu (TW)

(72) Inventors: Yu-Hsien Chiang, Hsinchu (TW); Wei-Yen Woon, Taoyuan City (TW); Szuya LIAO, Hsinchu (TW)

(73) Assignee: Taiwan Semiconductor Manufacturing Company, Ltd., Hsinchu (TW)

(21) Appl. No.: 19/752,692

(22) Filed: Jul. 24, 2026

Related U.S. Application Data
(63) Continuation of application No. 18/432,027, filed on Feb. 4, 2024.

(51) Int. Cl. H10D 30/43; H10D 30/01; H10D 30/67; H10D 62/10; H10D 62/13

(52) U.S. Cl. CPC H10D 30/43; H10D 30/014; H10D 30/6735; H10D 30/6757; H10D 62/121; H10D 62/151

(57) ABSTRACT

Provided are a semiconductor structure including high kappa (high-κ) material for source/drain (S/D) and/or thermal heat spreader and a method of forming the same. The semiconductor device includes a substrate, a plurality of channel layers stacked over the substrate, a gate structure wrapping the plurality of channel layers, and source/drain (S/D) regions disposed over the substrate at opposite sides of the gate structure and connecting the plurality of channel layers. A material of the S/D regions includes a high thermal conductivity material with a single crystal structure, such as boron arsenide (BAs) with a thermal conductivity greater than 1000 W/mK. In this case, the high thermal conductivity material can efficiently dissipate the heat generated by the semiconductor structure to enhance the yield and the reliability of the semiconductor structure.

### CROSS-REFERENCE TO RELATED APPLICATION

This application is a continuation application of and claims the priority benefit of a prior application Ser. No. 18/432,027, filed on Feb. 4, 2024, now pending. The entirety of the above-mentioned patent application is hereby incorporated by reference herein and made a part of this specification.

### BACKGROUND

Technological advances in Integrated Circuit (IC) materials and design have produced generations of ICs where each generation has smaller and more complex circuits than the previous generations. In the course of IC evolution, functional density (for example, the number of interconnected devices per chip area) has generally increased while geometry sizes have decreased. This scaling down process generally provides benefits by increasing production efficiency and lowering associated costs.

Such scaling down has also increased the complexity of processing and manufacturing ICs and, for these advances to be realized, similar developments in IC processing and manufacturing are needed. For example, multi-gate devices have been introduced to replace planar transistors. On the other hands, more different components with different materials are involved, which implies a demand on thermal management and heat dissipation efficiency due to high power density of ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is an isometric view of a nanosheet transistor in accordance with some embodiments.

FIG. 2 is a flow diagram of a method of forming a semiconductor structure in accordance with some embodiments.

FIGS. 3-7 are cross-sectional views of intermediate stages in the formation of the semiconductor structure in accordance with some embodiments.

FIG. 8 is a flow diagram of a method of forming a semiconductor structure in accordance with some embodiments.

FIGS. 9-14 are cross-sectional views of intermediate stages in the formation of the semiconductor structure in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is generally related to semiconductor structures and the fabrication thereof, and more particularly to multi-gate transistors. Multi-gate transistors include those transistors whose gate structures are formed on at least two-sides of a channel region. These multi-gate devices may include a p-type metal-oxide-semiconductor device or an n-type metal-oxide-semiconductor multi-gate device. Specific examples may be presented and referred to herein as FINFET, on account of their fin-like structure. Also presented herein are embodiments of a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), bar-shaped channel(s), and/or other suitable channel configurations. Presented herein are embodiments of devices that may have one or more channel regions (e.g., nanosheets) associated with a single, contiguous gate structure. However, one of ordinary skill would recognize that the teaching can apply to a single channel (e.g., single nanosheets) or any number of channels. One of ordinary skill may recognize other examples of semiconductor devices that may benefit from aspects of the present disclosure.

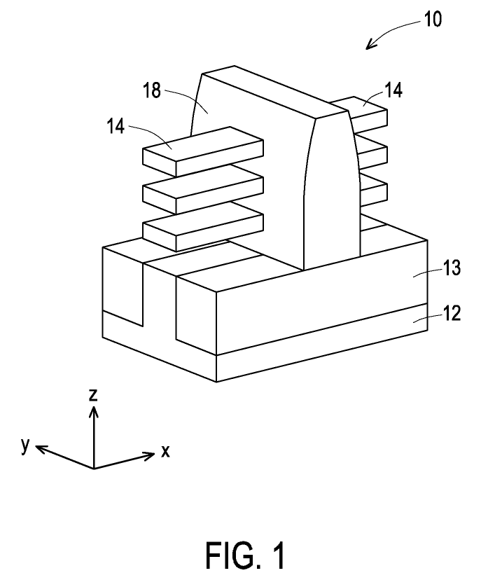

Nanostructure field effect transistors (FETs) include, for example, FinFETs, nanosheet transistors, nanowire transistors, gate-all-around FETs (GAAFETs), multi bridge channel transistors, and nano-ribbon transistors. FIG. 1 shows an isometric view of a nanosheet transistor 10 having a plurality of nanosheets 14 stacked over a substrate 12 and a gate structure 18 wrapping the nanosheets 14, in which active regions are separated from one another by isolation regions 13.

Embodiments of the present disclosure are shown and described, by way of example, as the nanosheet transistor 10, where the nanosheet transistor 10 has a plurality of channels 14 with a silicon (Si)-containing material. The channels 14 as described herein may also be applied to other types of FETs—for example, FinFETs, GAAFETs, nanowire FETs, complementary field-effect transistors (CFETs), or 2D planar FETs.

The Si-containing material may have good electron mobility, but poor hole mobility. In addition, silicon is not very good at conducting heat, which is why overheating issues and expensive cooling systems are common in electronic products. In this case, the thermal management of modern electronic devices has become very important.

In accordance with some embodiments, a novel material with a high thermal conductivity (e.g., boron arsenide (BAs)) may be used to replace the traditional Si-containing material (e.g., epitaxial silicon (Si) or silicon germanium (SiGe)) to form BAs source/drain (S/D) regions in the nanostructure FETs. BAs is able to overcome the heat dissipation challenges in the integrated circuit (IC) manufacturing with growing power density, so as to dissipate the heat generated by the nanostructure FETs, thereby enhancing the yield and the reliability of the nanostructure FETs. In addition, this novel material shows excellent high mobility for both electrons and holes to increases the switching speed, thereby improving the device performance. Further, BAs can also be used as a heat spreader in the back end-of-line (BEOL) process due to the high thermal conductivity (greater than 1000 W/mK).

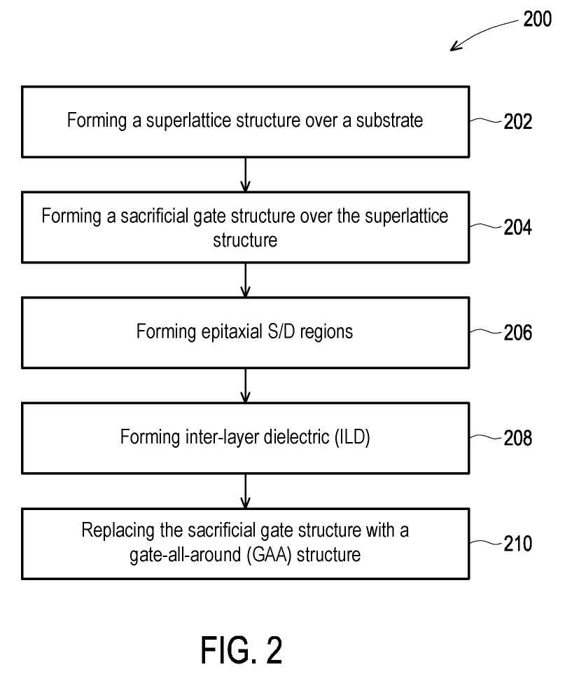

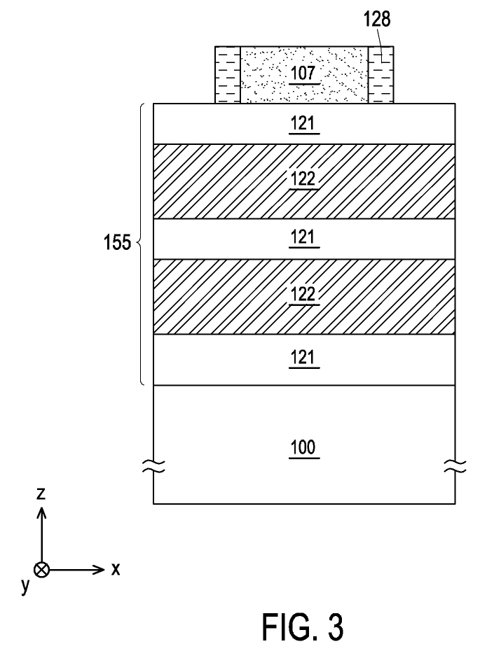

FIG. 2 illustrates operations in a method 200 of forming a semiconductor structure with reference to FIGS. 3-7 in accordance with some embodiments. The semiconductor structure illustrated in the following embodiments takes a nanosheet transistor as an example embodiment. However, the embodiments of the present disclosure are not limited thereto. In some other embodiments, the semiconductor structure may be applied to, but not limited thereto, various types of nanostructure FETs, such as FinFETs, nanowire transistors, gate-all-around FETs (GAAFETs), multi bridge channel transistors, nano-ribbon transistors, CFETs, or a combination thereof. Operations can be performed in a different order, or not performed, depending on specific applications. It is noted that method 200 may not produce complete nanosheet transistor. Accordingly, it is understood that additional processes can be provided before, during, or after method 200, and that some of these additional processes may only be briefly described herein.

Referring to FIG. 2, in the operation 202, a superlattice structure 155 may be formed on a substrate 100, as shown in FIG. 3. In some embodiments, the substrate 100 includes a crystalline silicon substrate (e.g., wafer). The substrate 100 may include various doped regions (e.g., p-type well and/or n-type well) depending on design requirements. In some embodiments, the doped regions may be doped with p-type or n-type dopants. For example, the doped regions may be doped with p-type dopants, such as boron or BF₂; n-type dopants, such as phosphorus or arsenic; and/or combinations thereof. The doped regions may be configured for an n-type nanosheet FETs, or alternatively, configured for a p-type nanosheet FETs. For clarity, the doped regions are not illustrated in FIG. 3 and subsequent drawings. In some alternative embodiments, the substrate 100 includes an element semiconductor such as silicon or germanium, a compound semiconductor such as silicon carbide, gallium arsenic, gallium phosphide, indium phosphide, indium arsenide and indium antimonide, an alloy semiconductor such as SiGe, GaAsP, AlInAs, AlGaAs, GaInAs, GaInP and GaInAsP or combinations thereof.

In some embodiments, the superlattice structure 155 is in the form of a multilayer nanosheet stack. The superlattice structure 155 may include a stack of the nanostructure channel layers 121 and the nanostructure sacrificial layers 122 arranged alternately. In some embodiments, the nanostructure sacrificial layers 122 may be in contact with the substrate 100. In some alternative embodiments, the nanostructure channel layers 121 may be in contact with the substrate 100. In some embodiments, the superlattice structure 155 is formed by depositing a stack of two different semiconductor layers arranged in the alternating configuration. The nanostructure channel layers 121 and the nanostructure sacrificial layers 122 may have different materials with different etching selectivities, so that the nanostructure sacrificial layers 122 are replaced in subsequent processing, while the nanostructure channel layers 121 remain as part of the nanosheet transistor. Although FIG. 3 shows three nanostructure channel layers 121 and two nanostructure sacrificial layers 122, any number of nanostructure layers can be included in each superlattice structure 155.

In some embodiments, the nanostructure channel layers 121 and the nanostructure sacrificial layers 122 include different materials. For example, the nanostructure sacrificial layers 122 are SiGe layers having a germanium percentage in the range between about 15 wt% and 40 wt%, and the nanostructure channel layers 121 are Si layers free from germanium. However, the embodiment of the disclosure is not limited thereto, in other embodiments, the nanostructure channel layers 121 and the nanostructure sacrificial layers 122 have materials with different etching selectivities. In some embodiments, the nanostructure channel layers 121 and the nanostructure sacrificial layers 122 are formed by an epitaxial growth process, such as a molecular beam epitaxy (MBE) process, a metalorganic chemical vapor deposition (MOCVD) process, or the like. In the case, the nanostructure channel layers 121 are epitaxial Si layers, and the nanostructure sacrificial layers 122 are epitaxial SiGe layers. In some alternative embodiments, the nanostructure channel layers 121 and the nanostructure sacrificial layers 122 are formed by a suitable deposition, such as chemical vapor deposition (CVD), atomic layer deposition (ALD), or the like. In the case, the nanostructure channel layers 121 are poly-Si layers, and the nanostructure sacrificial layers 122 are poly-SiGe layers.

In some embodiments, the nanostructure channel layers 121 include materials similar to one another, e.g., epitaxial Si, while nanostructure sacrificial layers 122 include materials similar to one another, e.g., epitaxial SiGe. The alternating configuration of the superlattice structure 155 may be achieved by alternating deposition, or epitaxial growth, of Si and SiGe layers, starting from the substrate 100. The thickness of each of the nanostructure layers 121 and 122 may be adjusted according to the technology node, and the embodiments of the present disclosure is not limited thereto. In some embodiments, the topmost nanostructure layers (e.g., Si layers) of the superlattice structure 155 may be thicker than the underlying nanostructure layers.

The superlattice structure 155 may be formed via an epitaxial growth process. The epitaxial growth process may include a combination of deposition operations and epitaxial growth operations, such as chemical vapor deposition (CVD), such as plasma-enhanced CVD (PECVD), thermal CVD, low pressure CVD (LPCVD), rapid thermal chemical vapor deposition (RTCVD), metal-organic chemical vapor deposition (MOCVD), atomic layer CVD (ALCVD), ultrahigh vacuum CVD (UHVCVD), reduced pressure CVD (RPCVD), or another suitable CVD process. In some embodiments, layers of the superlattice structure 155 may be grown by selective epitaxial growth (SEG), where an etching gas can be added to promote selective growth on exposed semiconductor surfaces, but not on insulating material.

In some embodiments, the epitaxial growth process may involve one or more silicon or SiGe precursor gases, such as silane (SiH₄), di-silane (Si₂H₆), germane (GeH₄), and di-germane (Ge₂H₆) to form epitaxial Si and/or epitaxial SiGe used as the nanostructure channel layers 121 and/or the nanostructure sacrificial layers 122. Doping of the superlattice structure 155 may also be determined by introducing one or more precursors during the above-noted epitaxial growth process. For example, the superlattice structure 155 may be in-situ p-type or n-type doped during the epitaxial growth process using p-type or n-type doping precursors.

Referring again to FIG. 2, following formation of the superlattice structure 155, in the operation 204, a sacrificial gate structure 107 may be formed on the superlattice structure 155, as shown in FIG. 3. The sacrificial gate structure 107 may include a polysilicon gate structure having sidewall spacers 128. The polysilicon gate structure may be deposited and then patterned using a hard mask, e.g., an oxide material that may be grown and/or deposited using an ALD process. The sacrificial gate structure 107 will later be replaced by a metal gate-all-around (GAA) structure 158.

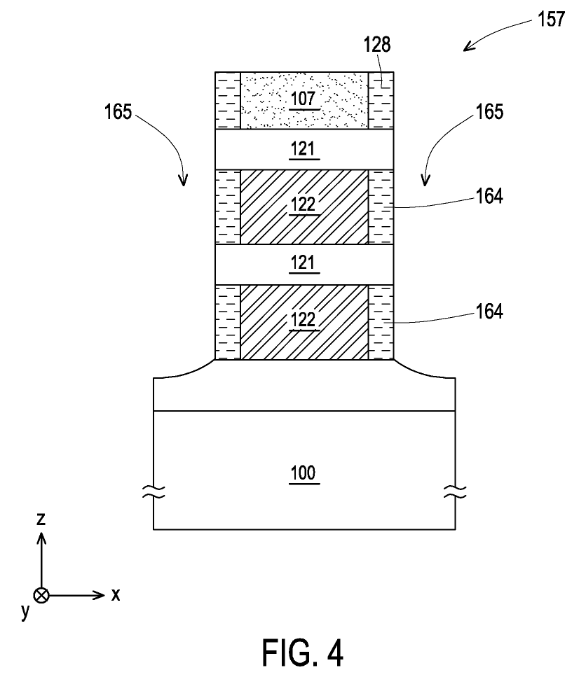

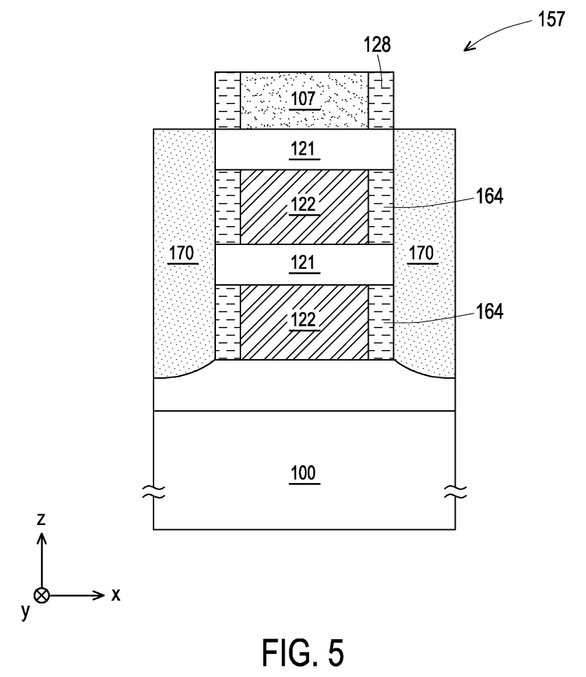

Referring to FIG. 2, in the operation 206, epitaxial S/D regions 170 may be formed, as shown in FIG. 5. Specifically, end portions of the superlattice structure 155 may be removed and recessed to form recesses 165, as shown in FIG. 4. Herein, the recesses 165 may be referred to as source/drain (S/D) recesses 165. In some embodiments, the end portions of the superlattice structure 155 may be removed by an anisotropic etching process, an isotropic etching process, a combination thereof, or any suitable etching process as described above. Following the S/D recess process, layers of the superlattice structure 155 remain in a channel region 157 underneath sacrificial gate structure 107 as shown in FIG. 4. After forming the S/D recesses 165, portions of the nanostructure sacrificial layers 122 are laterally recessed, to form a plurality of cavities between the nanostructure channel layers 121. Then, a dielectric material is formed to fill in the cavities to form inner spacers 164 between the nanostructure sacrificial layers 122 and the S/D recesses 165. After forming the inner spacers 164, epitaxial S/D regions 170 are formed in the S/D recesses 165 to connect the nanostructure channel layers 121, as shown in FIG. 5.

Specifically, the epitaxial S/D regions 170 may include a high thermal conductivity material with a single crystal structure. In some embodiments, the epitaxial S/D regions 170 is formed of boron arsenide. In some embodiments, the epitaxial S/D regions 170 includes boron arsenide bulk. In some embodiments, the epitaxial S/D regions 170 does not have silicon or silicon-containing material. In the present embodiment, a material of the epitaxial S/D regions 170 includes boron arsenide (BAs) with a thermal conductivity greater than 1000 W/mK. For example, the thermal conductivity of the epitaxial S/D regions 170 may be between 1000 W/mK and 1500 W/mK, such as 1100 W/mK, 1200 W/mK, 1300 W/mK, 1400 W/mK, or 1500 W/mK, including any range between any two of the preceding values. Specifically, the material of the epitaxial S/D regions 170 may be cubic boron arsenide (c-BAs) with the single crystal structure. In such embodiment, c-BAs can efficiently dissipate the heat generated by the nanostructure FETs, thereby enhancing the yield and the reliability of the nanostructure FETs. In addition, c-BAs shows excellent high electron and hole mobility to increases the switching speed, thereby improving the device performance.

In some embodiments, the epitaxial S/D regions 170 may be formed via an epitaxial growth process, such as PECVD, thermal CVD, LPCVD, RTCVD, MOCVD, ALCVD, UHVCVD, RPCVD, or another suitable CVD process. In some embodiments, the epitaxial growth process may involve a boron (B)-containing precursor and an arsenic (As)-containing precursor to form epitaxial BAs with the thermal conductivity greater than 1000 W/mK used as the epitaxial S/D regions 170. Specifically, the B-containing precursor may include diborane, boron-halides (BF₃, BCl₃, BBr₃), triethyl boron, trimethyl boron, borazine, or a combination thereof; and the As-containing precursor comprises Arsine (AsH₃), Tertiarybutylarsine, Trimethylarsine, Diethyltertiarybutylarsine, or a combination thereof. The B-containing precursor and the As-containing precursor may be injected into the chamber separately via two gas lines. In PECVD is an example embodiment to form BAs as the epitaxial S/D regions 170, the growth temperature may be 200˚C-700˚C, the process pressure may be 0.01 torr-40 torr, and the plasma frequency may vary between 40KHz and 40MHz. In thermal CVD is an example embodiment to form BAs as the epitaxial S/D regions 170, the growth temperature may be 400˚C-750˚C and the process pressure may be 0.1 torr-30 torr. It should be noted that, in the present embodiment, the epitaxial growth process can achieve the large-scale deposition (approximate 300 mm wafer size) single crystal BAs layers. The uniform and defect-free BAs layer with 300 mm industrial size shows excellent heat dissipation capability and carrier mobility which can be used in the semiconductor structure to achieve large-scale commercial production.

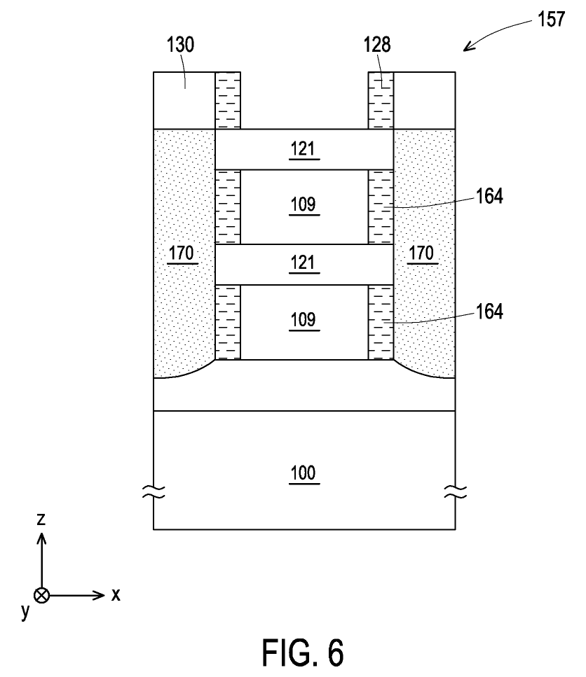

Referring to FIG. 2, in the operation 208, an inter-layer dielectric (ILD) 130 may be formed, as shown in FIG. 6, through which electrical contacts (not shown) may be made to source, drain, and gate terminals of nanosheet FETs. The ILD 130 may include silicon dioxide or a low-k dielectric material such as, for example, a fluorosilicate glass, a carbon-doped silicon dioxide, a porous silicon dioxide, a porous carbon-doped silicon dioxide, a hydrogen silsesquioxane, a methylsilsesquioxane, a polyimide, a polynorbomene, a benzocyclobutene and/or a polytetrafluoroethylene. For forming the ILD 130, a deposition process such as, for example, chemical vapor deposition, plasma-enhanced chemical vapor deposition and/or spin coating may be performed.

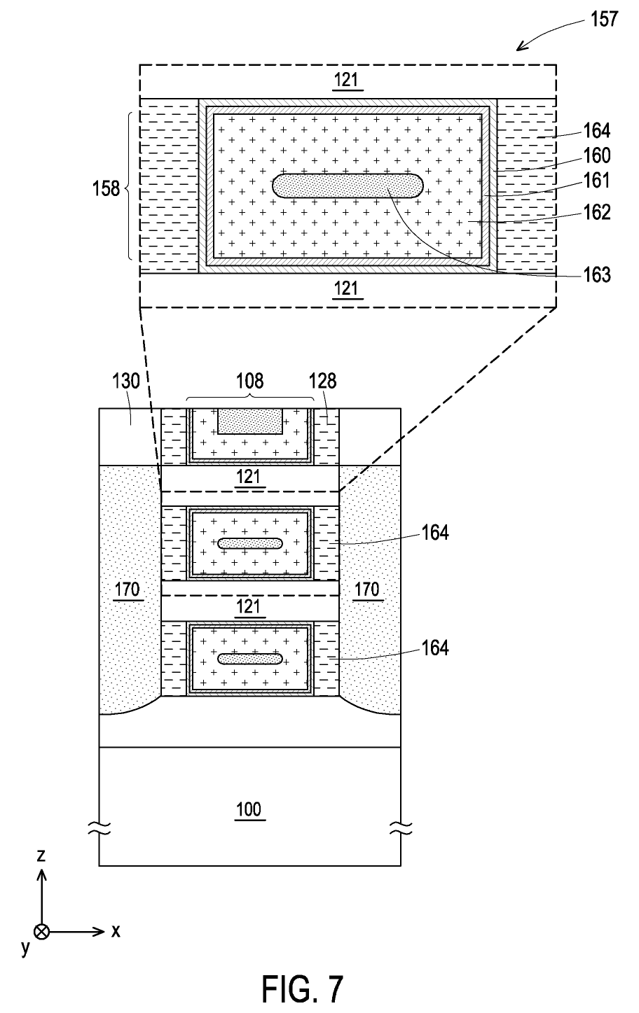

Referring to FIG. 2, in the operation 210, the sacrificial gate structure 107 may be removed and replaced with a gate-all-around structure, as shown in FIGS. 6-7. In the operation 210, the nanostructure sacrificial layers 122 are selectively removed to form gate openings 109 in the channel region 157, as shown in FIG. 6. The gate openings 109 are then filled with metal by depositing the gate structure 108, to complete GAA channel region 157, as shown in FIG. 7.

FIGS. 3-7 are magnified views showing operations for forming gate structure 108 and GAA channel region 157, according to some embodiments. With reference to FIG. 7, the GAA channel region 157 may include a plurality of GAA structures 158, which wrap the channel layers 121 to control current flow therein. Each GAA structure 158 may be viewed as a radial gate stack that includes, from the outermost layer to the innermost layer, an interface layer 160, a gate dielectric layer 161, a work function metal layer 162, and a gate electrode 163. The gate electrode 163 is operable to maintain a capacitive applied voltage across the nanostructure channel layers 121. The gate dielectric layer 161 may separate the metallic layers of the GAA structure 158 from the nanostructure channel layers 121. The inner spacers 164 may electrically isolate the GAA structure 158 from the epitaxial S/D region 170 and prevent current from leaking out of the nanostructure channel layers 121.

FIG. 3 is a magnified cross-sectional view of the superlattice structure 155 and the sacrificial gate structure 107.

FIG. 4 is a magnified cross-sectional view of the GAA channel region 157 following formation of the S/D recesses 165 and the inner spacers 164.

FIG. 5 is a magnified cross-sectional view of the GAA channel region 157 following formation of the epitaxial S/D regions 170, which may be grown laterally outward, in the x-direction, from the nanostructure layers 121.

FIG. 6 is a magnified cross-sectional view of the GAA channel region 157, following extraction of the nanostructure sacrificial layers 122 and thus forming the gate openings 109. First, the sacrificial gate structure 107 is removed, leaving the sidewall spacers 128 in place. Then, the nanostructure sacrificial layers 122 are removed to form the gate openings 109. As a result, the nanostructure channel layers 121 are suspended.

FIG. 7 is a magnified view of the GAA channel region 157, following replacement of the sacrificial gate structure 107 with the gate structure 108. The gate structure 108 is grown in a multi-step process to form a metal gate stack in place of the sacrificial gate structure 107. Simultaneously, the radial gate stack is formed to fill the gate openings 109 from the outside in, starting with the interface layer 160, and ending with the gate electrode 163.

Referring to FIG. 7, the interface layer 160 may be conformally formed over the gate openings 109 and the space between sidewall spacers 128. In some embodiments, the interface layer 160 includes a dielectric material, such as silicon oxide layer (SiO₂) or silicon oxynitride (SiON). In some embodiments, the interface layer 160 is formed by a deposition process, such as atomic layer deposition (ALD), chemical vapor deposition (CVD), and/or other suitable deposition methods. In some alternative embodiments, the interface layer 160 is formed by oxidizing the nanostructure channel layers 121 through chemical oxidation or thermal oxidation. In some embodiments, the interface layer 160 is adapted to provide a good interface between the semiconductor surface and the gate insulator and to suppress the mobility degradation of the channel carrier of the nanosheet FET.

The gate dielectric layer 161 may be conformally disposed on the interface layer 160. In some embodiments, the gate dielectric layer 161 includes a high-k material, where the term “high-k” refers to a high dielectric constant. In the field of semiconductor device structures and manufacturing processes, high-k refers to a dielectric constant that is greater than the dielectric constant of SiO₂ (e.g., greater than about 3.9), greater than about 7, greater than about 12, greater than about 16, or even greater than about 20. For example, a material of the high-k material may include metal oxide, such as ZrO₂, Gd₂O₃, HfO₂, BaTiO₃, Al₂O₃, LaO₂, TiO₂, Ta₂O₅, Y₂O₃, STO, BTO, BaZrO, HfZrO, HfLaO, HfTaO, HfTiO, a combination thereof, or a suitable material. In some alternative embodiments, the high-k material may optionally include a silicate such as HfSiO, HfSiON LaSiO, AlSiO, a combination thereof, or a suitable material. In some embodiments, the gate dielectric layer 161 is formed by performing at least one suitable deposition technique, such as CVD, PECVD, MOCVD, ALD, remote plasma atomic layer deposition (RPALD), plasma-enhanced atomic layer deposition (PEALD), molecular beam deposition (MBD), or the like. In some embodiments, the gate dielectric layer 161 may include a single layer or multiple insulating material layers.

The gate work function metal layer 162 may include a single metal layer or a stack of metal layers. The stack of metal layers can include metals having work functions similar to or different from each other. In some embodiments, the gate work function metal layer 162 may include, for example, aluminum (Al), copper (Cu), tungsten (W), titanium (Ti), tantalum (Ta), cobalt (Co), metal nitrides, metal silicides, metal alloys, and/or combinations thereof. The gate work function metal layer 162 may be formed using a suitable process, such as ALD, CVD, PVD, plating, and combinations thereof.

The gate electrode 163 may further include a gate metal fill layer. The gate metal fill layer may include a single metal layer or a stack of metal layers. The stack of metal layers may include metals different from each other. In some embodiments, the gate metal fill layer may include one or more suitable conductive materials or alloys, such as Ti, Al, TiN, and the like. The gate metal fill layer may be formed by ALD, PVD, CVD, or other suitable deposition process. Other materials, dimensions, and formation methods for the interface layer 160, the gate dielectric layer 161, the gate work function metal layer 162, and the gate electrode 163 are within the scope and spirit of this disclosure.

Following formation of the gate structures 108 and the GAA structures 158 in the GAA channel regions 157, the structure of nanosheet FETs are substantially accomplished.

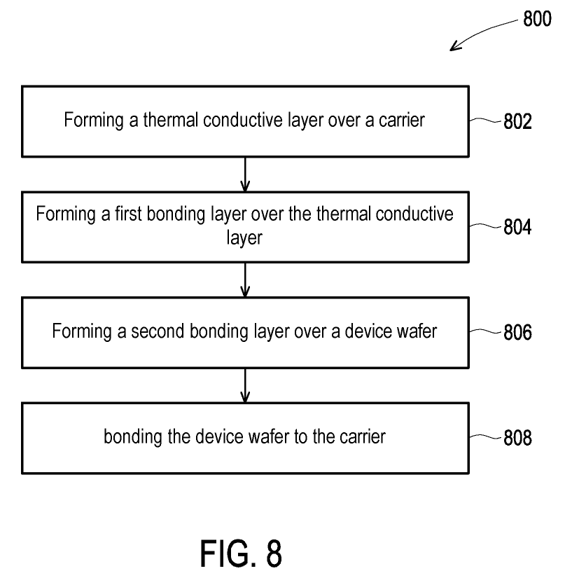

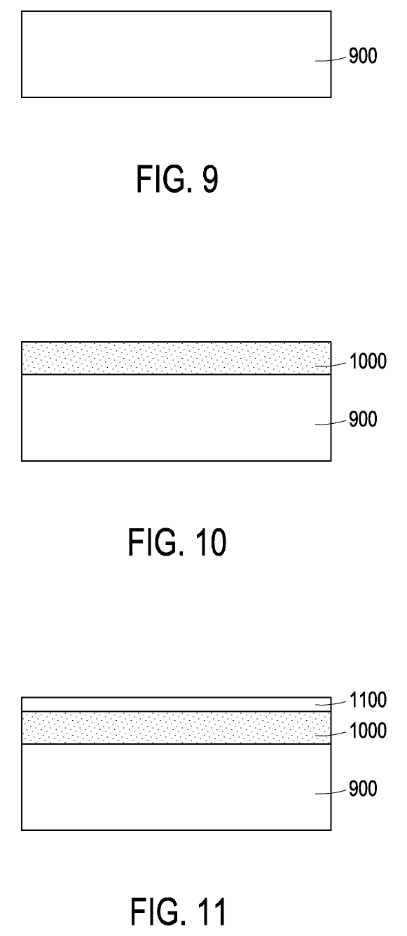

FIG. 8 illustrates operations in a method 800 of forming a semiconductor structure with reference to FIGS. 9-14 in accordance with some embodiments. The semiconductor structure illustrated in the following embodiments takes a wafer stack structure as an example embodiment. However, the embodiments of the present disclosure are not limited thereto. In some other embodiments, the novel material with the high thermal conductivity (e.g., boron arsenide (BAs)) may be applied to, but not limited thereto, various types of BEOL processes for heat dissipation. Operations can be performed in a different order, or not performed, depending on specific applications. It should be understood that additional processes can be provided before, during, or after method 800, and that some of these additional processes may only be briefly described herein.

Referring to FIG. 8, in the operation 802, a thermal conductive layer 1000 may be formed over a carrier 900, as shown in FIGS. 9-10. In some embodiments, the carrier 900 may be a glass carrier substrate, a ceramic carrier substrate, a wafer (e.g., a silicon wafer), or the like. The carrier 900 may provide structural support during subsequent processing steps and heat dissipation in the completed device.

In some embodiments, a material of the thermal conductive layer 1000 includes a high kappa (high-κ) material with a single crystal structure. In the present embodiment, a material of the thermal conductive layer 1000 includes boron arsenide (BAs) with a thermal conductivity greater than 1000 W/mK. For example, the thermal conductivity of the thermal conductive layer 1000 may be between 1000 W/mK and 1500 W/mK, such as 1100 W/mK, 1200 W/mK, 1300 W/mK, 1400 W/mK, or 1500 W/mK, including any range between any two of the preceding values. Specifically, the material of the thermal conductive layer 1000 may be cubic boron arsenide (c-BAs) with the single crystal structure. In such embodiment, c-BAs can efficiently dissipate the heat generated by subsequently bonded device wafer 1200 (FIG. 13), thereby enhancing the yield and the reliability of the semiconductor structure.

In some embodiments, the thermal conductive layer 1000 may be formed via an epitaxial growth process, such as PECVD, thermal CVD, LPCVD, RTCVD, MOCVD, ALCVD, UHVCVD, RPCVD, or another suitable CVD process. In some embodiments, the epitaxial growth process may involve a boron (B)-containing precursor and an arsenic (As)-containing precursor to form epitaxial BAs with the thermal conductivity greater than 1000 W/mK used as the thermal conductive layer 1000. Specifically, the B-containing precursor may include diborane, boron-halides (BF₃, BCl₃, BBr₃), triethyl boron, trimethyl boron, borazine, or a combination thereof; and the As-containing precursor comprises Arsine (AsH₃), Tertiarybutylarsine, Trimethylarsine, Diethyltertiarybutylarsine, or a combination thereof. The B-containing precursor and the As-containing precursor may be injected into the chamber separately via two gas lines. In PECVD is an example embodiment to form BAs as the thermal conductive layer 1000, the growth temperature may be 200˚C-700˚C, the process pressure may be 0.01 torr-40 torr, and the plasma frequency may vary between 40KHz and 40MHz. In thermal CVD is an example embodiment to form BAs as the thermal conductive layer 1000, the growth temperature may be 400˚C-750˚C and the process pressure may be 0.1 torr-30 torr. It should be noted that, in the present embodiment, the epitaxial growth process can achieve the large-scale deposition (approximate 300 mm wafer size) single crystal BAs layers. The uniform and defect-free BAs layer with 300 mm industrial size shows excellent heat dissipation capability and carrier mobility which can be used in the semiconductor structure to achieve large-scale commercial production.

Referring again to FIG. 8, following formation of the thermal conductive layer 1000, in the operation 804, a first bonding layer 1100 may be formed over the thermal conductive layer 1000, as shown in FIG. 11. In some embodiments, the first bonding layer 1100 may include an insulating material that is suitable for a subsequent dielectric-to-dielectric bonding process. Example materials for the first bonding layer 1100 include silicon oxide (e.g., SiO₂), silicon nitride, silicon oxynitride, silicon carbonitride, silicon oxycarbonitride, or the like. The first bonding layer 1100 may be formed by deposited by any suitable process, such as PVD, CVD, ALD, or the like.

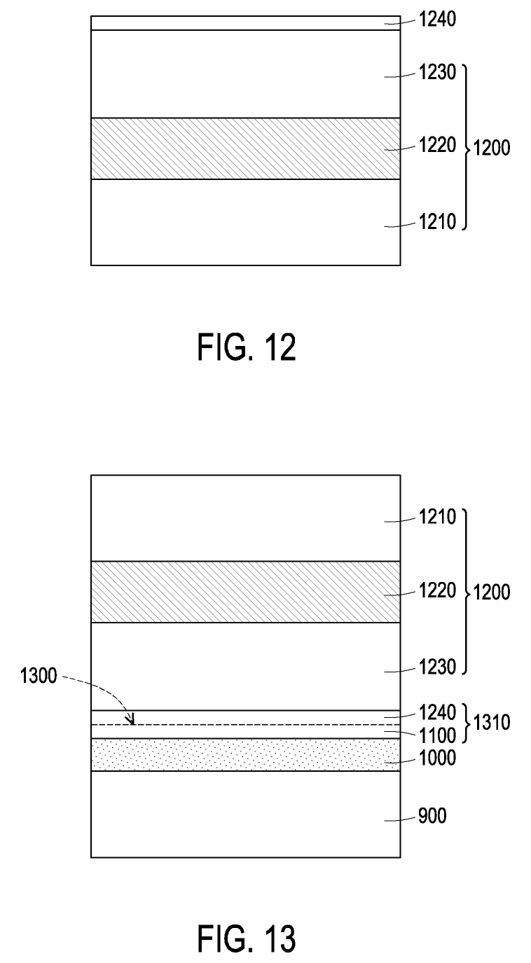

Referring to FIG. 8, in the operation 806, a second bonding layer 1240 may be formed over a device wafer 1200, as shown in FIG. 12. Specifically, the device wafer 1200 may include a semiconductor substrate 1210, a device layer 1220, and a first interconnect structure 1230.

In some embodiments, the semiconductor substrate 1210 may include silicon or other semiconductor materials. Alternatively, or additionally, the semiconductor substrate 1210 may include other elementary semiconductor materials such as germanium. In some embodiments, the semiconductor substrate 1210 is made of a compound semiconductor such as silicon carbide, gallium arsenic, indium arsenide or indium phosphide. In some embodiments, the semiconductor substrate 1210 is made of an alloy semiconductor such as silicon germanium, silicon germanium carbide, gallium arsenic phosphide, or gallium indium phosphide. In some embodiments, the semiconductor substrate 1210 includes an epitaxial layer. For example, the semiconductor substrate 1210 has an epitaxial layer overlying a bulk semiconductor.

In some embodiments, the device layer 1220 is formed on the semiconductor substrate 1210 in a front-end-of-line (FEOL) process. The device layer 1220 includes a wide variety of devices. In some embodiments, the devices comprise active components, passive components, or a combination thereof. In some embodiments, the devices may include integrated circuits devices. The devices are, for example, transistors, capacitors, resistors, diodes, photodiodes, fuse devices, or other similar devices. In some embodiments, the device layer 1220 includes a gate structure, source/drain regions, and isolation structures, such as shallow trench isolation (STI) structures (not shown). In the device layer 1220, various N-type metal-oxide semiconductor (NMOS) and/or P-type metal-oxide semiconductor (PMOS) devices, such as transistors or memories and the like, may be formed and interconnected to perform one or more functions. Other devices, such as capacitors, resistors, diodes, photodiodes, fuses and the like may also be formed on the semiconductor substrate 1210. The functions of the devices may include memory, processors, sensors, amplifiers, power distribution, input/output circuitry, or the like.

In some embodiments, the first interconnect structure 1230 is formed over the device layer 1220. In detail, the first interconnect structure 1230 includes an insulating material and a plurality of metal features. The metal features may be formed in the insulating material and electrically connected with each other. In some embodiments, the insulating material includes an inner-layer dielectric (ILD) layer on the semiconductor substrate 1210, and at least one inter-metal dielectric (IMD) layer over the ILD layer. In some embodiments, the insulating material includes silicon oxide, silicon oxynitride, silicon nitride, low dielectric constant (low-k) materials or a combination thereof. In some alternatively embodiments, the insulating material may be a single layer or multiple layers. In some embodiments, the metal features include plugs and metal lines. The plugs may include contacts formed in the ILD layer, and vias formed in the ILD layer. The contacts are formed between and in connect with the device layer 1220 and a bottom metal line. The vias are formed between and in connect with two metal lines. The metal features may be made of tungsten (W), copper (Cu), copper alloys, aluminum (Al), aluminum alloys, or a combination thereof. In some alternatively embodiments, a barrier layer (not shown) may be formed between the metal features and the insulating material to prevent the material of the metal features from migrating to the device layer 1220. A material of the barrier layer includes tantalum, tantalum nitride, titanium, titanium nitride, cobalt-tungsten (CoW) or a combination thereof, for example.

In some embodiments, the second bonding layer 1240 may include an insulating material that is suitable for a subsequent dielectric-to-dielectric bonding process. Example materials for the second bonding layer 1240 include silicon oxide (e.g., SiO₂), silicon nitride, silicon oxynitride, silicon carbonitride, silicon oxycarbonitride, or the like. The second bonding layer 1240 1100 may be formed by deposited by any suitable process, such as PVD, CVD, ALD, or the like. A material composition of the second bonding layer 1240 may be the same or different than a material composition of the first bonding layer 1100.

Referring to FIG. 8, in the operation 808, the device wafer 1200 may be bonded to the carrier 900, as shown in FIG. 13. In some embodiments, the device wafer 1200 may be bonded to the carrier 900 with the thermal conductive layer 1000 thereon by the bonding layers 1100 and 1240. Specifically, the bonding layers 1100 and 1240 may be bonded together using a suitable technique, such as dielectric-to-dielectric bonding, or the like. After bonding, the first bonding layer 1100 and the second bonding layer 1240 may be collectively referred to as a bonded layer 1310. The bonded layer 1310 may or may not have an interface 1300 disposed therein where the first bonding layer 1100 meets the second bonding layer 1240. From another perspective, the device wafer 1200 may be bonded to the carrier 900 by directly contacting the first bonding layer 1100 with the second bonding layer 1240 at the interface 1300. It should be noted that the heat generated from the device layer 1220 of the device wafer 1200 can be dissipated to the carrier 900 through the thermal conductive layer 1000 with the thermal conductivity greater than 1000 W/mK. As a result, the yield and the reliability of the semiconductor structure can be improved due to efficient heat dissipation.

In some embodiments, the dielectric-to-dielectric bonding process includes applying a surface treatment to one or more of the bonding layers 1100 and 1240 to form hydroxyl (OH) groups at bonding surfaces of the bonding layers 1100 and 1240. The surface treatment may include a plasma treatment, such as a nitrogen (N₂) plasma treatment. After the plasma treatment, the surface treatment may further include a cleaning process that may be applied to one or more of the bonding layers 1100 and 1240. The second bonding layer 1240 may then be placed over and aligned to the first bonding layer 1100. The two bonding layers 1100 and 1240 are then pressed against each other to initiate a pre-bonding of the upper device wafer 1200 to the lower carrier 900. The pre-bonding may be performed at room temperature (e.g., in a range of 20˚C to 28˚C). After the pre-bonding, an annealing process may be applied by, for example, heating the device wafer 1200 and the carrier 900 to a temperature of in a range of 300˚C to 500˚C. The annealing process drives or triggers the formation of covalent bonds between the bonding layers 1100 and 1240.

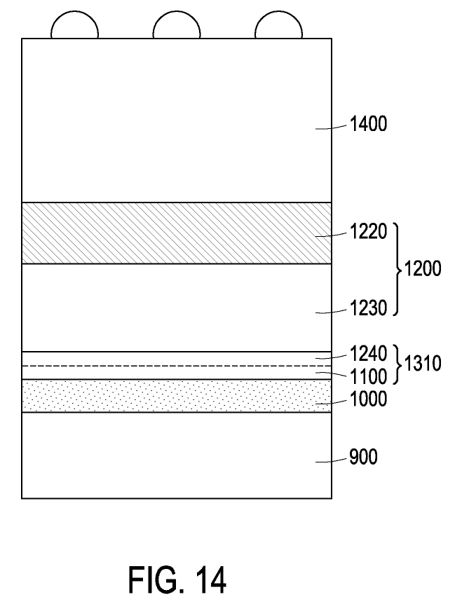

Referring to FIGS. 13-14, after bonding the device wafer 1200 with the carrier 900, a thinning process is performed to reduce a thickness of the device wafer 1200 to a desired thickness. The thinning process may include a grinding process, a chemical mechanical polish (CMP), an etch back process, combination thereof, or the like. In some embodiments, the thinning process may remove the semiconductor substrate 1210 of the device wafer 1200 to expose the device layer 1220.

As shown in FIG. 14, a second interconnect structure 1400 may be formed over a backside of the device wafer 1200. Specifically, the second interconnect structure 1400 includes an insulating material and a plurality of metal features. The metal features may be formed in the insulating material and electrically connected with each other. In some embodiments, the metal features may be formed to connect with the device layer 1220. The second interconnect structure 1400 may be formed of a similar material using similar processes as those discussed above with respect to the first interconnect structure 1230. In some embodiments, the second interconnect structure 1400 may be referred to as the back-side interconnect structure, while the first interconnect structure 1230 may be referred to as the front-side interconnect structure.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

According to some embodiments, a semiconductor device includes a substrate, a plurality of channel layers stacked over the substrate, a gate structure wrapping the plurality of channel layers, and source/drain (S/D) regions disposed over the substrate at opposite sides of the gate structure and connecting the plurality of channel layers. A material of the S/D regions includes a high thermal conductivity material with a single crystal structure.

According to some embodiments, a method of forming a semiconductor structure includes: forming a superlattice structure over a substrate, wherein the superlattice structure includes a plurality of nanostructure channel layers stacked alternately; forming a gate structure to wrap the plurality of nanostructure channel layers; and forming source/drain (S/D) regions over the substrate at opposite sides of the gate structure to connect the plurality of nanostructure channel layers, wherein the S/D regions comprises a high kappa (high-κ) material with a single crystal structure.

According to some embodiments, a method of forming a semiconductor structure includes: forming a thermal conductive layer over a carrier, wherein a material of the thermal conductive layer comprises a high kappa (high-κ) material with a single crystal structure; forming a first bonding layer over the thermal conductive layer; forming a second bonding layer over a device wafer; and bonding the device wafer to the carrier, so that a heat generated from the device wafer is dissipated to the carrier through the thermal conductive layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor structure, comprising:
forming a superlattice structure over a substrate, wherein the superlattice structure includes a plurality of nanostructure channel layers stacked alternately;
forming a gate structure to wrap the plurality of nanostructure channel layers; and
forming source/drain (S/D) regions over the substrate at opposite sides of the gate structure to connect the plurality of nanostructure channel layers, wherein each of the S/D regions comprises a high kappa (high-κ) material with a single crystal structure.

2. The method of forming the semiconductor structure of claim 1, wherein the forming the superlattice structure comprises:
performing an epitaxial growth process to form a plurality of nanostructure sacrificial layers and the plurality of nanostructure channel layers arranged alternately, wherein the plurality of nanostructure sacrificial layers and the plurality of nanostructure channel layers have different materials with different etching selectivities.

3. The method of forming the semiconductor structure of claim 1, wherein the forming the S/D regions comprises:
removing a portion of the superlattice structure to form S/D recesses; and
performing an epitaxial growth process to form the S/D regions in the S/D recesses.

4. The method of forming the semiconductor structure of claim 3, wherein the epitaxial growth process comprises using a boron (B)-containing precursor and an arsenic (As)-containing precursor to form boron arsenide (BAs) with a thermal conductivity greater than 1000 W/mK used as a corresponding S/D region.

5. The method of forming the semiconductor structure of claim 4, wherein the B-containing precursor comprises diborane, boron-halides (BF₃ BCl₃ BBr₃), triethyl boron, trimethyl boron, borazine, or a combination thereof.

6. The method of forming the semiconductor structure of claim 4, wherein the As-containing precursor comprises Arsine (AsH₃), Tertiarybutylarsine, Trimethylarsine, Diethyltertiarybutylarsine, or a combination thereof.

7. The method of forming the semiconductor structure of claim 1, wherein the high-κ material comprises boron arsenide (BAs) with a thermal conductivity greater than 1000 W/mK.

8. The method of forming the semiconductor structure of claim 1, wherein each of the S/D regions is cubic boron arsenide (c-BAs) with the single crystal structure.

9. The method of forming the semiconductor structure of claim 1, wherein each of the S/D regions is free of silicon or silicon-containing material.

10. A semiconductor structure, comprising:
a carrier;
a thermal conductive layer disposed over the carrier, wherein a material of the thermal conductive layer comprises a high kappa (high-κ) material with a single crystal structure;
a first bonding layer disposed over the thermal conductive layer; and
a device layer having a second bonding layer thereon, wherein the device layer is bonded to the thermal conductive layer by the second bonding layer interfacing with the first bonding layer.

11. The semiconductor structure of claim 10, wherein the high-κ material comprises boron arsenide (BAs) with a thermal conductivity greater than 1000 W/mK.

12. The semiconductor structure of claim 10, wherein the thermal conductive layer is cubic boron arsenide (c-BAs) with the single crystal structure.

13. The semiconductor structure of claim 10, wherein the thermal conductive layer is free of silicon or silicon-containing material.

14. The semiconductor structure of claim 10, further comprising: a first interconnect structure interposed between the device layer and the second bonding layer.

15. The semiconductor structure of claim 14, further comprising: a second interconnect structure disposed on a surface of the device layer opposite to the first interconnect structure, wherein the device layer is interposed between the first and second interconnect structures.

16. A method of forming a semiconductor structure, comprising:
forming a thermal conductive layer over a carrier, wherein a material of the thermal conductive layer comprises a high kappa (high-κ) material with a single crystal structure;
forming a first bonding layer over the thermal conductive layer;
forming a second bonding layer over a device component; and
bonding the device component to the carrier, so that a heat generated from the device component is dissipated to the carrier through the thermal conductive layer.

17. The method of forming the semiconductor structure of claim 16, wherein the forming the thermal conductive layer comprises using a boron (B)-containing precursor and an arsenic (As)-containing precursor to form boron arsenide (BAs) with a thermal conductivity greater than 1000 W/mK.

18. The method of forming the semiconductor structure of claim 17, wherein the B-containing precursor comprises diborane, boron-halides (BF₃ BCl₃ BBr₃), triethyl boron, trimethyl boron, borazine, or a combination thereof.

19. The method of forming the semiconductor structure of claim 17, wherein the As-containing precursor comprises Arsine (AsH₃), Tertiarybutylarsine, Trimethylarsine, Diethyltertiarybutylarsine, or a combination thereof.

20. The method of forming the semiconductor structure of claim 16, wherein the device component is bonded to the carrier by directly contacting the first bonding layer with the second bonding layer.
